(19) United States
(12) Patent Application Publication
(10) Pub. No.: US 2009/0253264 A1
(43) Pub. Date: Oct. 8, 2009

(54) THIN FILM FORMATION METHOD AND MANUFACTURING METHOD FOR SEMICONDUCTOR DEVICE

(75) Inventor: Junichi Horie, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/189,335

(22) Filed: Aug. 11, 2008

(30) Foreign Application Priority Data
Apr. 7, 2008 (JP) 2008-099005

(51) Int. Cl. H01L 21/311

(52) U.S. Cl. 438/694; 257/E21.249

(57) ABSTRACT

A method of forming a thin film including a first portion having a first film thickness and a second portion having a second film thickness thinner than the first film thickness. A thin film having the first film thickness is formed on a substrate, an interference waveform upon film formation from reflected light by irradiating with laser light is acquired, the second portion of the thin film is etched, an interference waveform upon etching is acquired by irradiating, with laser light, the second portion, and calculating an interference waveform upon target etching on condition that the second portion has the second film thickness, based on the interference waveform upon film formation. The etching is stopped when the interference waveform upon etching becomes the same as the interference waveform upon target etching.

### BACKGROUND OF THE INVENTION

1. Field of the Invention

The present invention relates to a thin film formation method for performing film formation and etching to form a thin film including a first portion having a first film thickness and a second portion having a second film thickness thinner than the first film thickness, and a manufacturing method for semiconductor devices.

2. Background Art

Upon etching a thin film formed on a substrate, dry etching is often used for reasons of easy micro-fabrication, resist selectivity, etc. In dry etching, for example, etching gas or ions and the like are supplied to areas in which the thin film is exposed from resist opening portions. The etching gas or ions and the like react chemically and physically to a material of the thin film. Thus, the thin film as the etching material is etched.

In the above-mentioned etching, it may be requested to etch to a desired depth neither too much nor too little. In other words, there is a case where control of a remaining film after etching is important. Examples of cases where control of a remaining film after etching is important include the channel formation of ridge waveguide laser and the formation of wiring contact holes. Thus, the suppression of unevenness after etching is often important to stabilize device characteristics. Then, it is necessary to detect an end point to stop etching with a high degree of accuracy in order to etch neither too much nor too little.

In etching a thin film, the end point of etching is detected, and according to the location at which the etching should be stopped, the etching technique is classified into the following two techniques: First, it is a technique for stopping etching at the interface of a multilayer film or at the interface between the thin film and the substrate (hereinafter called the interface stop type). Second, it is a technique for stopping etching in such a manner to form a thin film having a thick portion and a thin portion in the same thin film (hereinafter called the halfway stop type). In other words, the halfway stop type etching means that part of the formed thin film is made thinner than the other parts.

In the above-mentioned halfway stop type etching, the end point of etching is often detected from measurement data of the amount of etching. However, the film thickness of the thin film after film formation has certain unevenness. Therefore, there is a problem that the remaining film after etching can be uneven even if the amount of etching made after the film formation is even. For example, the unevenness of the remaining film can adversely affect the stabilization of characteristics of the semiconductor device.

Here, the method of end point detection disclosed in Patent Document 1(Japanese Patent Application Laid-Open No. 55-104482) is such that a derivative of reflected light of a light beam irradiated onto a wafer surface during etching is determined and compared with criteria to detect the end point. The method of Patent Document 1 is to stop the etching at the interface between the thin film and another thin film or between the thin film and the substrate. Therefore, this method can be performed for the interface stop type etching, but it has drawbacks in that the method cannot be available for halfway stop type etching because the intensity of an interference waveform obtained during etching the same thin film is often constant. Even in other Patent Documents, there is another problem that the remaining film cannot be kept at a constant value in a simple process for both the interface stop type and halfway stop type.

### SUMMARY OF THE INVENTION

The present invention has been made to solve the above-mentioned problems, and it is an object thereof to provide a thin film formation method and a manufacturing method for semiconductor devices, which have excellent controllability with respect to a remaining film and keep constant the film thickness of the remaining film after etching even if the film thickness of the thin film after film formation is constant.

According to one aspect of the present invention, a thin film formation method including a first portion having a first film thickness and a second portion having a second film thickness thinner than the first film thickness, includes following steps. A step of acquiring an interference waveform upon film formation as an interference waveform of a reflected wave obtained by irradiating, with laser, the thin film upon film formation, a step of etching the second portion of the thin film, a step of acquiring an interference waveform upon etching as an interference waveform of a reflected wave obtained by irradiating, with laser, the second portion upon etching, and a step of calculating an interference waveform upon target etching as the interference waveform upon etching on condition that the second portion has the second film thickness based on the interference waveform upon film formation. In the step of etching the second portion, the etching is stopped at the time when the interference waveform upon etching becomes the interference waveform upon target etching.

Other and further objects, features and advantages of the invention will appear more fully from the following description.

### BRIEF DESCRIPTION OF THE DRAWINGS

FIG. 1 is system conceptual diagram;

FIG. 2 is a flowchart for explaining the thin film formation method of the embodiment;

FIG. 3 is a sectional view showing a multilayer film;

FIG. 4 is the interference waveforms upon film formation;

FIG. 5 is etching shape obtained by the present invention;

FIG. 6 shows the interference waveform upon target etching;

FIG. 7 shows the interference waveform upon etching assuming that all the thin films formed in the film formation apparatus are etched;

FIG. 8 shows a system of the comparative example;

FIG. 9 is the substrate during etching of the comparative example; and

FIG. 10 shows adverse effect of the comparative example.

### DETAILED DESCRIPTION OF THE PREFERRED EMBODIMENT

### Embodiment

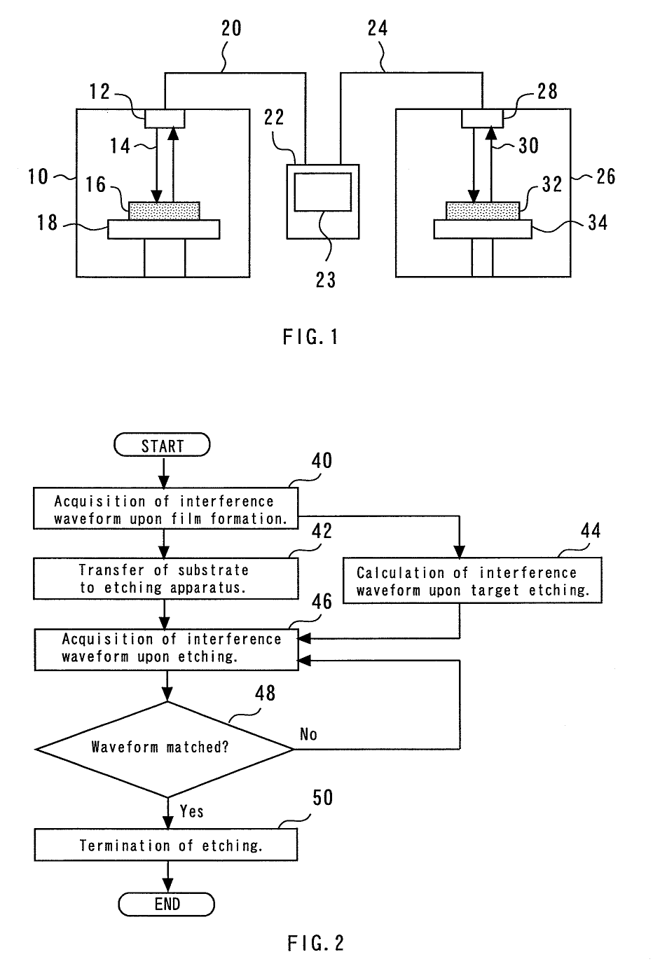

The thin film formation method and the manufacturing method for semiconductor devices according to the embodiment are often used for mainly manufacturing semiconductor devices. However, since it can be generally applied to the formation of a thin film, it is called the “thin film formation method.” A system for performing the thin film formation method of the embodiment includes a film formation apparatus, an etching apparatus, and a controller. Referring now to FIG. 1 as a system conceptual diagram, these components of the embodiment will be described. The system of the embodiment includes a film formation apparatus 10. In the film formation apparatus 10, a stage 18 for placing a substrate 16 thereon is provided. In the film formation apparatus 10, a thin film is formed on condition that the substrate 16 is placed on the stage 18. Further, the film formation apparatus 10 is provided with a laser irradiation/receiving section 12. The laser irradiation/receiving section 12 irradiates laser onto the film formation surface of the substrate 16 during film formation, and receives reflected light.

The system of the embodiment further includes an etching apparatus 26. In the etching apparatus 26, a stage 34 for placing a substrate 32 thereon is provided. In the etching apparatus 26, a thin film of the substrate 32 is etched on condition that the substrate 32 is placed on the stage 34. Note that the substrate 32 is the substrate 16 on which a film is formed in the film formation apparatus 10 and transferred to the etching apparatus. The substrates 16, 32 are just illustrative examples for convenience, and the details of them will be described later. Like the film formation apparatus 10, the etching apparatus 26 is provided with a laser irradiation/receiving section 28. The laser irradiation/receiving section 28 irradiates with laser an etching surface (surface on which etching is performed, and hereinafter the same) of the substrate 32 during etching, and receives reflected light.

The system of the embodiment further includes a controller 22. The controller 22 is connected to the laser irradiation/receiving section 12 via an optical fiber 20. Further, the controller 22 is also connected to the laser irradiation/receiving section 28 via an optical fiber 24. Then, the controller 22 is provided with a laser interferometer 23. The laser interferometer 23 is to acquire an interference waveform of a reflected wave acquired in the laser irradiation/receiving section 12 or the laser irradiation/receiving section 28. The interference waveform obtained from the laser interferometer 23 becomes a target for a predetermined calculation to be described later.

FIG. 2 is a flowchart for explaining the thin film formation method of the embodiment. Referring to FIG. 2, step 40 will be described. First, in step 40, a substrate is placed on the stage 18 of the film formation apparatus 10. Then, film formation is started in such a manner to form a desired thin film. Here, laser irradiation is performed from the laser irradiation/receiving section 12 onto the substrate surface on which a film is formed concurrently with or before the start of the film formation. Then, the reflected wave of the laser light is incident into the laser irradiation/receiving section 12. The above-mentioned reflected wave reaches the laser interferometer 23 via the optical fiber 20. The laser interferometer 23 acquires an interference waveform upon film formation as an interference waveform of the reflected wave to accumulate data in the controller 22. The acquisition of the interference waveform upon film formation is continued at least from the start to the end of the film formation.

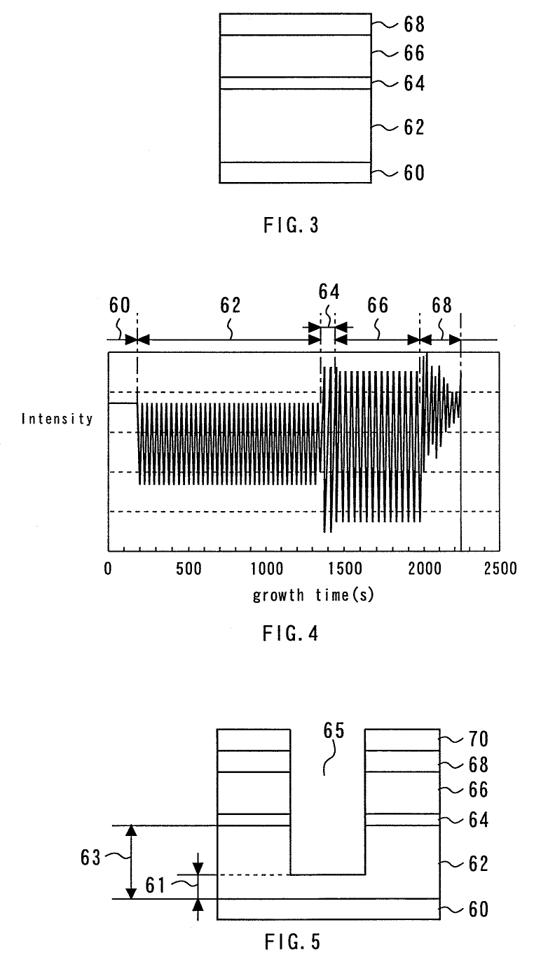

FIG. 3 is a sectional view showing a multilayer film as a thin film formed in step 40. When film formation using the film formation apparatus 10 is performed in step 40, a thin filmA 62 is formed on a substrate 60, a thin filmB 64 on the thin filmA 62, a thin filmC 66 on the thin filmB 64, and a thin filmD 68 on the thin filmC 66. Here, though the composition of each thin film is not particularly limited, the following combination can be considered in terms of the manufacturing process for semiconductor laser. Namely, the thin filmA 62 is defined as a lower cladding layer of the semiconductor laser. Then, the thin filmB 64 is defined as an active layer of the semiconductor laser, the thin filmC 66 is defined as an upper cladding layer of the semiconductor laser, and the thin filmD 68 is defined as a contact layer of the semiconductor laser. Further, each thin film can be formed by a crystal growth method such as epitaxial crystal growth. However, the film formation method for a thin film is not particularly limited as long as the interference waveform upon film formation can be acquired.

Here, the interference waveforms upon film formation obtained from the formation of the thin filmA 62 to the formation of the thin filmD 68 are shown in FIG. 4. The symbols attached in FIG. 4 show which thin film corresponds to each of the waveforms. It will easily be understood from FIG. 4 that an interference waveform having intensity inherent to each of thin films upon film formation is obtained for each of thin films forming the multilayer film in the embodiment. Thus, if the obtained interference waveforms upon film formation are referred to, it is easy to identify the interference waveforms of the thin films A, B, C, D.

Upon completion of processing step 40, the processing proceeds to step 42 or step 44. In step 42, the substrate on which the thin film was formed in step 40 is transferred from the film formation apparatus 10 to the etching apparatus 26. This is preparation for performing etching in such a manner to make part of the thin film thinner than the other parts in the etching apparatus 26 after the formation of the thin film in the film formation apparatus 10.

On the other hand, step 44 is a process for calculating an interference waveform upon target etching as an index upon stopping the etching before actual etching to be described later. This calculation is made by the controller 22. Here, the interference waveform upon target etching is used in the etching process to be described later as follows, namely: the etching is stopped when an interference waveform (hereinafter called the interference waveform upon etching) obtained from a reflected wave as a result of irradiating laser onto the etching surface in the etching process matches the interference waveform upon target etching.

Here, the etching performed by the thin film formation method of the embodiment is illustrated in order to explain the details of step 44. The thin film formation method of the embodiment aims to perform etching of part of the thin filmA 62, the thin filmB 64, the thin filmC 66, and the thin filmD 68 after forming the thin film in step 40 in order to obtain a structure shown in FIG. 5. The structure shown in FIG. 5 has a resist 70 formed in part of the thin film. Then, the thin filmB 64, the thin filmC 66, and the thin filmD 68 are etched in a resist opening portion 65. Further, the thin filmA 62 formed to a first film thickness 63 in the resist opening portion 65 is etched in such a manner to have a second film thickness 61.

In step 44, an interference waveform (indicated by 62 in FIG. 4) corresponding to the thin filmA 62 in FIG. 4 as the interference waveform upon film formation is identified. Then, the number of periods (called a frequency equivalent to the first film thickness) existing in the identified interference waveform is counted. Next, the number of periods (called a frequency equivalent to the second film thickness) in the interference waveform is calculated from the start of formation of the thin filmA 62 until the thin filmA 62 is made to have the second film thickness 61 in the film formation. For example, if it is desired that the second film thickness 61 in the thin filmA 62 becomes the film thickness one-half the first film thickness 63, one-half the frequency equivalent to the first film thickness is the frequency equivalent to the second film thickness.

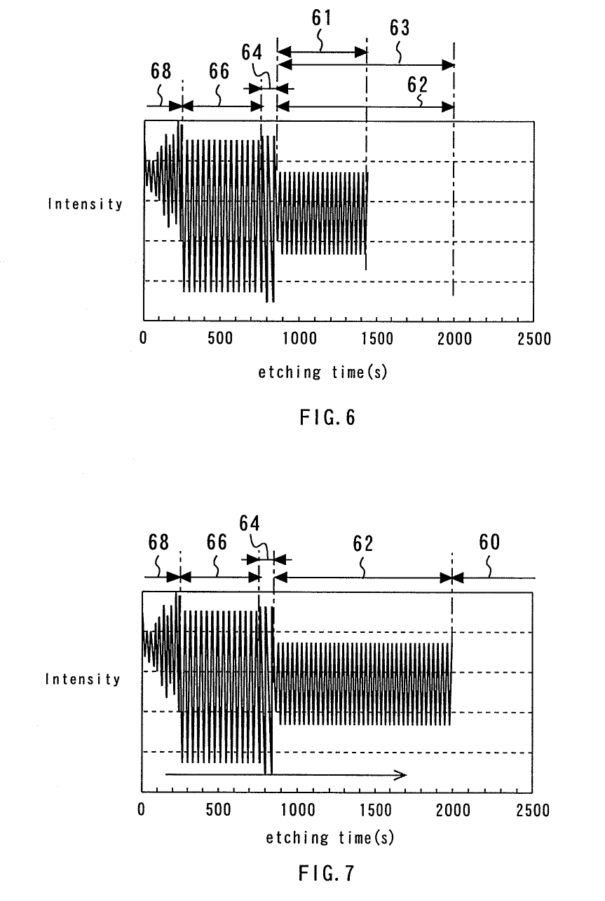

In step 44, the interference waveform upon film formation obtained by subtracting the frequency equivalent to the second film thickness from the number of periods in a waveform portion corresponding to the thin filmA 62 is defined as an interference waveform upon target etching by reversing the start point and the end point of the waveform. Here, the reason for reversing the start point and the end point is that the interference waveform upon target etching is accumulated in a direction from the end point of the interference waveform upon film formation toward the start point. FIG. 6 shows the interference waveform upon target etching obtained by the above-mentioned method. The interference waveform upon target etching is reduced to an interference waveform corresponding to the frequency equivalent to the second film thickness (indicated by 61 in FIG. 6) in a region of the interference waveform of the thin filmA 62 from the frequency equivalent to the first film thickness (indicated by 63 in FIG. 6). In step 44, the interference waveform upon target etching is stored in the controller 22.

After completion of step 42 or step 44, the processing proceeds to step 46. In step 42, etching is performed in the resist opening portions 65 (onto the etching surface) after the formation of the resist 70 in order to obtain an etching shape shown in FIG. 5. Then, laser is irradiated from the laser irradiation/receiving section 28 to the opening portion 65 at least during etching. Further, the reflected wave of the above-mentioned laser is incident into the laser irradiation/receiving section 28 and reaches the laser interferometer 23 via the optical fiber 24. The laser interferometer 23 acquires the interference waveform upon etching as the interference waveform of the reflected wave to accumulate data in the controller 22. The controller 22 accumulates the interference waveform upon etching as shown in FIG. 7.

FIG. 7 shows the interference waveform upon etching assuming that all the thin films A to D formed in the film formation apparatus 10 are etched. This is just an illustrative example for convenience. Actually, since etching is stopped when the interference waveform upon etching matches the interference waveform upon target etching, there is no case that could obtain the interference waveform upon etching more than that shown in FIG. 6.

In step 46, while the etching is performed and the interference waveform upon etching is accumulated, it is rated whether the interference waveform upon etching matches the interference waveform upon target etching. This rating is performed by the controller 22 at constant intervals. The interference waveform upon target etching used for the rating is stored in the controller 22. As shown in step 48, it is not rated that the interference waveform upon etching matches the interference waveform upon target etching as a result of investigation, the etching is continued. On the other hand, if it is rated that the interference waveform upon etching matches the interference waveform upon target etching, the etching is ended (step 50). According to the embodiment, whether the interference waveform upon etching matches the interference waveform upon target etching is evaluated as to whether both the numbers of periods match with each other. However, whether the interference waveform upon etching matches the interference waveform upon target etching can be evaluated by other means such as to compare both the numbers of peaks of both waveforms.

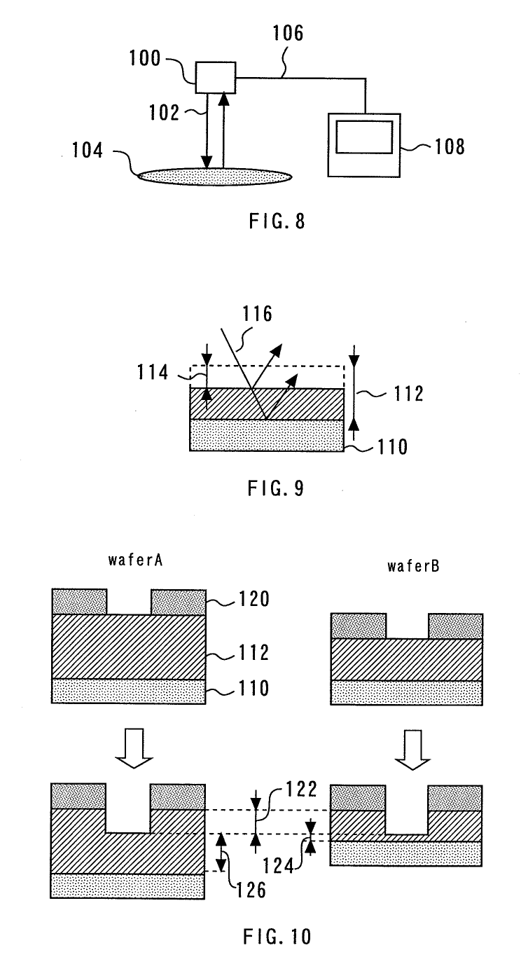

Here, a comparative example will be described in order to make the features of the present invention easy to understand. FIG. 8 shows a system of the comparative example. This system includes a substrate 104 to be etched, a laser irradiation/receiving section 100, an optical fiber 106, and a laser interferometer 108. The operation of the system is as follows, namely: laser is irradiated from the laser irradiation/receiving section 100 onto the substrate 104 during etching of the substrate 104. Then, the reflected wave from the substrate 104 reaches the laser interferometer 108 from the laser irradiation/receiving section 100 via the optical fiber 106.

The substrate 104 during etching is simplified, and the details are shown in FIG. 9. In the comparative example, a thin film 112 is formed on a substrate 110. At the time when the thin film 112 is etched and the amount of etching reaches the location represented as a film thickness 114, the etching is stopped. The amount of etching of the thin film 112 is determined by calculating an interference waveform occurring by an optical path difference, among the light 116 incident into the thin film 112, between light reflected on the topmost surface of the thin film 112 and light transmitted through the thin film 112 and reflected on the interface between the substrate 110 and the thin film 112. Thus, when the amount of etching becomes the film thickness 114, the etching is ended.

If the thin film is etched by managing the amount of etching in the comparative example, the remaining film becomes uneven. This adverse effect will be described by referring to wafer A and wafer B shown in FIG. 10. The thin film 112 is formed on the substrate 110 in case of both the wafer A and the wafer B (see the upper part of FIG. 10). Then, a resist 120 is formed to form an opening portion. The film thickness of the thin film 112 is different between the wafer A and the wafer B due to a process variation. Then, in the openings of both the wafer A and the wafer B, etching is performed in such a manner that the amount of etching becomes an amount of etching 122. After etching, in case of the wafer A, the remaining film in the opening portion has a film thickness 126. On the other hand, in case of the wafer B, the remaining film in the opening portion has a film thickness 124. Thus, the remaining films of the wafer A and the wafer B do not match with each other. For this reason, even if the amount of etching is controlled as in the comparative example, there is a problem that unevenness occurs in the remaining film after etching due to unevenness of the film formation between the wafers (or between lots).

According to the thin film formation method of the embodiment, the problem in the comparative example can be solved. In the embodiment, the interference waveform upon film formation is used to calculate the interference waveform upon target etching so as to perform etching until the interference waveform upon target etching matches the interference waveform upon etching. Therefore, in principle, the remaining film after etching is generated neither too much nor too little. In other words, even if the film thickness of the thin film formed in the film formation apparatus is uneven, the remaining film after etching can be made uniform.

In terms of film thickness controllability of the remaining film, it is preferable to acquire the interference waveform upon film formation for each wafer and calculate the etching waveform upon target etching. However, if the film thickness of the thin film is seldom uneven or can be negligible in a lot, the interference waveform upon target etching can be calculated on a lot-by-lot basis.

In the embodiment, the interference waveform upon target etching is so set that a waveform obtained by subtracting a second film thickness equivalent to the frequency from the number of periods of the waveform portion corresponding to the thin filmA 62 of the interference waveform upon film formation is obtained by reversing the start point and the end point of the waveform. However, the present invention is not limited thereto. In other words, instead of dealing with frequencies, the waveform from when the thin film starts growing until it has the second film thickness can be removed from the interference waveform upon film formation. As an example of such a removal method, there is a method for removing the above-mentioned number of periods.

Further, instead of dealing with the above-mentioned frequency, the film thickness of the thin film can be calculated from the interference waveform upon film formation to calculate the etching time in order to leave the remaining film having the second film thickness in case of thin film A. In this case, the acquisition of the interference waveform upon etching is not necessary.

Alternatively, the film thickness of the thin film after film formation is measured to calculate the film thickness of the thin film per unit period from the interference waveform upon film formation. Then, the number of periods corresponding to the remaining film after performing desired etching can be subtracted from the number of periods of the interference waveform upon film formation to determine the interference waveform upon target etching.

According to the features of the embodiment, the interference waveform upon film formation can be utilized for end point detection at the time of etching. Therefore, even if the film thickness of the thin film formed in the film formation process is uneven, the remaining film after etching can be freely controlled. Thus, the calculation method for the interference waveform upon target etching can be a method other than the above-mentioned method without departing from the scope of the present invention. Further, for example, the etching time can be calculated directly from the interference waveform upon film formation.

Although such a case where the multilayer film is etched in the embodiment has been described, even if the present invention is used for etching a thin film of a single layer, the effect of the present invention can be obtained in the same manner as the case of the multilayer film.

Although the halfway stop type etching is performed in the embodiment, even if the interface stop type etching is used, the effect of the present invention can be kept. In other words, even in the case of the interface stop type etching, since the interference waveform upon target etching can be calculated from the interference waveform upon film formation, film thickness control of the remaining film after etching as the effect of the present invention is enabled.

Since the present invention can freely control the remaining film after etching the thin film, the remaining film can be kept at a constant value.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-099005, filed on Apr. 7, 2008 including specification, claims, drawings and summary, on which the Convention priority of the present application is based, are incorporated herein by reference in its entirety.

1. A method of forming a thin film including a first portion having a first film thickness and a second portion having a second film thickness, thinner than the first film thickness, the method comprising:
forming the thin film having the first film thickness on a substrate;
acquiring an interference waveform upon film formation, as a first interference waveform of reflected light, by irradiating, with laser light, the thin film upon film formation;
etching the second portion of the thin film;
of acquiring an interference waveform upon etching as a second interference waveform of reflected light, by irradiating, with laser light, the second portion; and
calculating an interference waveform for target etchings as a third interference waveform, on condition that the second portion has the second film thickness, based on the first interference waveform wherein, in etching the second portion, stopping the etching when the second interference waveform becomes the same the third interference waveform.

2. The method according to claim 1, wherein, in calculating the third interference waveform, an interference waveform is removed from the first interference waveform, obtained from starting of the forming of the thin film until the thin film has the second film thickness.

3. The method according to claim 2, wherein, in calculating the third interference waveform, by subtracting (i) the number of periods of the interference waveform obtained from starting of film formation of the thin film until the thin film has the second film thickness from (ii) the number of periods of the first interference waveform.

4. The thin film formation method according to claim 3, further comprising
measuring film thickness of the thin film after the forming the thin film,
calculating the film thickness of the thin film formed per unit period of the first interference waveform from the film thickness measured to determine the number of periods equivalent to the second film thickness, and
obtaining the second interference waveform by subtracting (i) the number of periods equivalent to the second film thickness from (ii) the number of periods of the interference waveform upon film formation,

5. The method according to claim 1, of including acquiring the first interference waveform and the second interference waveform in the same measurement apparatus.

6. A method for manufacturing a semiconductor device using the method according to claim 1.
